(19) United States
(12) Patent Application Publication
(10) Pub. No.: US 2012/0068215 A1
(43) Pub. Date: Mar. 22, 2012

(54) LIGHT EMITTING DEVICE

(75) Inventors: SangYoul LEE, Seoul (KR); JuneO SONG, Seoul (KR); KwangKi CHOI, Seoul (KR); HwanHee JEONG, Seoul (KR); HyeYoung KIM, Seoul (KR)

(73) Assignee: LG INNOTEK CO., LTD., Seoul (KR)

(21) Appl. No.: 13/284,124

(22) Filed: Oct. 28, 2011

(30) Foreign Application Priority Data
Oct. 28, 2010 (KR) 10-2010-0106183

(51) Int. Cl. H01L 33/50

(52) U.S. Cl. 257/98; 257/E33.06

(57) ABSTRACT

A light emitting device is provided. According to an embodiment, the light emitting device includes a first layer to diffuse first light emitted from the active layer, and a second layer to convert the diffused first light into second light having a different wavelength than the first light. Accordingly, it may be possible to diffuse first light emitted from the light emitting structure and to wavelength-convert the first light into second light because the conversion layer including the first and second layers is disposed on the light emitting structure.

### CROSS-REFERENCE TO RELATED APPLICATION

This application claims the priority benefit of Korean Patent Application No. 10-2010-0106183, filed in Korea on Oct. 28, 2010, the disclosure of which is incorporated herein by reference.

### BACKGROUND OF THE EMBODIMENT

1. Field

This relates to a light emitting device.

2. Background

Generally, a light emitting diode (LED) as a light emitting device is a semiconductor device, which emits light in accordance with recombination of electrons and holes. Such an LED is widely used as a light source in optical communications, electronic appliances, etc.

The frequency (or wavelength) of light emitted from an LED is a function of the bandgap of a material used in the LED. When a semiconductor material having a narrow bandgap is used, photons of low energy and long wavelengths are generated. On the other hand, when a semiconductor material having a wide bandgap is used, photons of short wavelengths are generated.

For example, an AlGaInP material generates red light. On the other hand, silicon carbide (SiC) and Group-III nitride-based semiconductors, in particular, GaN, generate light of blue or ultraviolet wavelengths.

Recently, light emitting devices are required to have high brightness so as to be used as light sources for illumination. In order to achieve such high brightness, research into manufacture of a light emitting device capable of achieving uniform current diffusion, and thus, enhancement in light emission efficiency, is being conducted.

### SUMMARY

Embodiments provide a light emitting device having a structure capable of easily avoiding degradation of a fluorescent layer formed over a light emitting structure.

In one embodiment, light emitting device comprises a light emitting structure comprising a first semiconductor layer, a second semiconductor layer, an active layer interposed between the first and second semiconductor layers, a first electrode electrically connected to the first semiconductor layer, a second electrode electrically connected to the second semiconductor layer, and formed through the first semiconductor layer and the active layer, an insulating layer disposed between the second electrode and the first electrode, between the second electrode and the first semiconductor layer and, a conversion layer disposed on the second semiconductor layer, the conversion layer comprising a first layer to diffuse first light emitted from the active layer, and a second layer to absorb the first light diffused by the first layer and to convert the first light into second light having a different wavelength than the first light.

In another embodiment, light emitting device comprises a substrate comprising first and second substrate portions spaced apart from each other, a light emitting structure dispose on the substrate, the light emitting structure comprising a first semiconductor layer, a second semiconductor layer, an active layer interposed between the first and second semiconductor layers, a first electrode interposed between the first substrate and the first semiconductor layer, and electrically connected to the first semiconductor layer, a second electrode disposed on the second substrate, formed through the first semiconductor layer and the active layer, and electrically connected to the second semiconductor layer, an insulating layer disposed between the second electrode and the first electrode, between the second electrode and the first semiconductor layer and second semiconductor layer and, a conversion layer disposed on the second semiconductor layer, the conversion layer comprising a first layer to diffuse first light emitted from the active layer, and a second layer to absorb the first light diffused by the first layer and to convert the first light into second light having a different wavelength than the first light.

In another embodiment, a light emitting device comprises a substrate, a light emitting structure dispose on the substrate, the light emitting structure comprising a first semiconductor layer, a second semiconductor layer, an active layer interposed between the first and second semiconductor layers, a first electrode electrically connected to the first semiconductor layer, a second electrode electrically connected to the second semiconductor layer, and formed through the first semiconductor layer and the active layer, an insulating layer disposed between the second electrode and the first electrode, between the second electrode and the first semiconductor layer and second semiconductor layer and, a conversion layer disposed on the second semiconductor layer, to perform diffusion and wavelength conversion for first light emitted from the active layer, wherein the conversion layer comprises a first layer to diffuse the first light, the first layer being formed with at least one opening at one or more surfaces of the first layer and a second layer disposed in the at least one opening, to absorb the first light and to convert the absorbed first light into second light having a different wavelength than the first light.

In addition, in the light emitting device according to one of the embodiments, the third layer, which has a low index of refraction, is interposed between the light emitting structure and the first layer. In this case, it may be possible to prevent back scattering of the first light and second light from the first and third layer toward the light emitting structure, and thus to achieve an enhancement in light emission efficiency.

### BRIEF DESCRIPTION OF THE DRAWINGS

The embodiments will be described in detail with reference to the following drawings in which like reference numerals refer to like elements wherein:

FIG. 1 is a perspective view illustrating a light emitting device in accordance with an embodiment as broadly described herein;

FIG. 2 is a cross-sectional perspective view of the light emitting device in accordance with an embodiment;

FIG. 3 is a cross-sectional perspective view of the light emitting device in accordance with another embodiment;

FIG. 4 is a view illustrating operation of the light emitting device;

FIGS. 5 to 9 are perspective views illustrating various arrangements of a first layer as embodied and broadly described herein;;

FIG. 10 is a perspective view illustrating a light emitting device in accordance with another embodiment as broadly described herein;

FIG. 11 is a cross-sectional perspective view of the light emitting device in accordance with another embodiment;

FIG. 12 is a cross-sectional view of a light emitting device package including a light emitting device as embodied and broadly described herein;

FIG. 13 is a perspective view of a lighting apparatus including a light emitting device in accordance embodiments as broadly described herein;

FIG. 14 is a sectional view of the lighting apparatus taken along the line A-A of the lighting device shown in FIG. 13;

FIG. 15 is a perspective view of a liquid crystal display apparatus including a light emitting device in accordance with an embodiment as broadly described herein; and

FIG. 16 is a perspective view of a liquid crystal display apparatus including a light emitting device in accordance with another embodiment as broadly described herein.

### DETAILED DESCRIPTION

Reference will now be made in detail to the preferred embodiments, examples of which are illustrated in the accompanying drawings.

Advantages and characteristics and methods for addressing the same will be clearly understood from the following embodiments taken in conjunction with the annexed drawings. However, embodiments are not limited and may be realized in other various forms. The embodiments are only provided to more completely illustrate and to render a person having ordinary skill in the art to fully understand the scope. The scope is defined only by the claims. Accordingly, in some embodiments, well-known processes, well-known device structures and well-known techniques are not illustrated in detail to avoid unclear interpretation. The same reference numbers will be used throughout the specification to refer to the same or like parts.

Spatially relative terms, “below”, “beneath”, “lower”, “above”, “upper” and the like may be used to indicate the relationship between one device or constituent elements and other devices or constituent elements, as shown in the drawings. It should be understood that the spatially relative terms include the direction illustrated in the drawings as well as other directions of devices during use or operation. For example, in a case in which the device shown in the drawing is reversed, a device arranged “below” or “beneath” the other device may be arranged “above” the other device. Accordingly, the exemplary term, “beneath” may include “below” or “beneath” and “above”. The device may be arranged in other directions. As a result, the spatially relative terms may be construed depending on orientation.

Terms used in the specification are only provided to illustrate the embodiments and should not be construed as limiting the scope and spirit of the present embodiments. In the specification, a singular form of terms includes plural forms thereof, unless specifically mentioned otherwise. In the term “comprises” and/or “comprising” as used herein, the mentioned component, step, operation and/or device is not excluded from presence or addition of one or more other components, steps, operations and/or devices.

Unless defined otherwise, all terms (including technical and scientific terms) used herein may be intended to have meanings understood by those skilled in the art. In addition, terms defined in general dictionaries should not be interpreted abnormally or exaggeratedly, unless clearly specifically defined.

In the drawings, the thicknesses or sizes of respective layers are exaggerated, omitted or schematically illustrated for clarity and convenience of description. Therefore, the sizes of respective elements do not wholly reflect actual sizes thereof.

In addition, angles and directions referred to during description of a structure of a light emitting device are described based on illustration in the drawings. In the description of the structure of the light emitting device, if reference points with respect to the angles and positional relations are not clearly stated, the related drawing will be referred to.

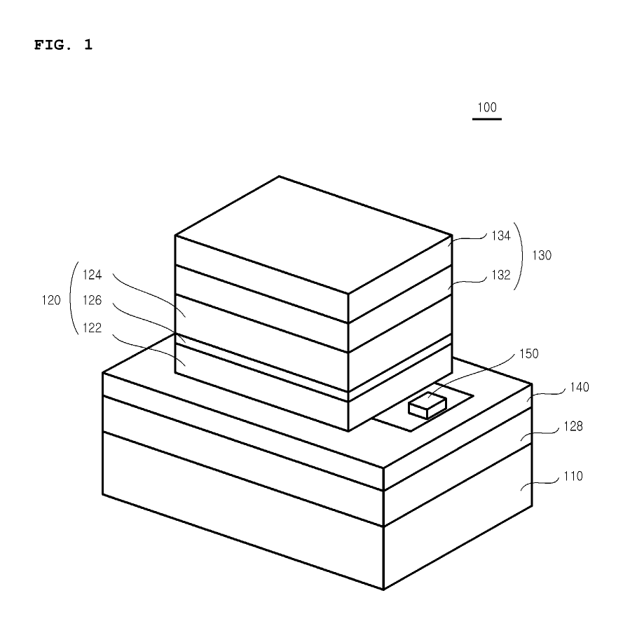

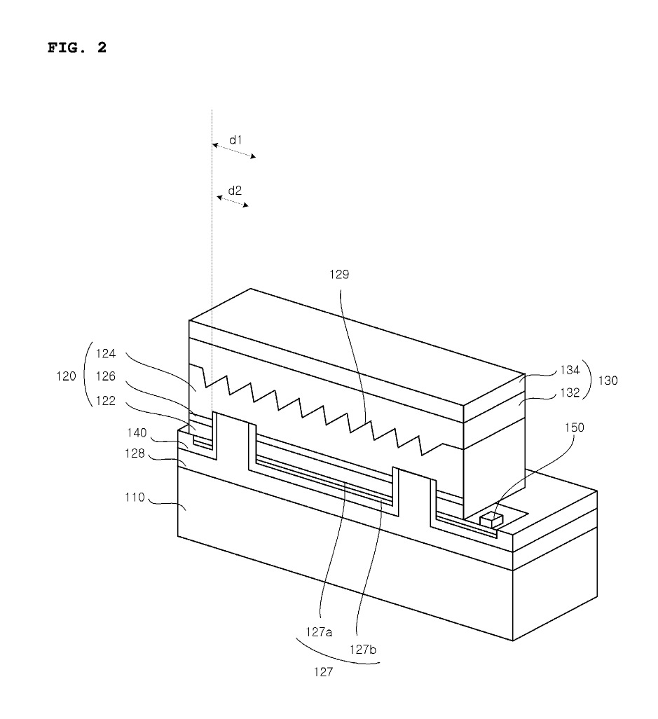

FIG. 1 is a perspective view illustrating a light emitting device in accordance with an embodiment as broadly described herein, and FIG. 2 is a cross-sectional perspective view of the light emitting device in accordance with an embodiment.

With reference to FIGS. 1 and 2, a light emitting device 100 as embodied and broadly described herein may include substrate 110, a light emitting structure 120, and a conversion layer 130.

The substrate 110 has light transmitting properties. The substrate 110 may be a substrate made of a material different from a semiconductor layer to be formed thereon, for example, a substrate made of a sapphire (Al₂O₃), or a substrate made of the same material as the semiconductor layer, for example, a substrate made of GaN. Alternatively, the substrate 110 may be a substrate made of silicon carbide (SiC) having higher thermal conductivity than the sapphire (Al₂O₃) substrate. Of course, the substrate 110 is not limited to the above-described materials.

For example, the substrate 110 may be made of zinc oxide (ZnO), gallium nitride (GaN), aluminum nitride (AlN) or the like. Alternatively, the substrate 110 may be made of, for example, at least one of gold (Au), nickel (Ni), tungsten (W), molybdenum (Mo), copper (Cu), aluminum (Al), tantalum (Ta), silver (Ag), platinum (Pt), chromium (Cr), and alloys thereof. The substrate 110 may be formed by laminating two or more layers of different materials.

The substrate 110 may have a single-layer structure. Alternatively, the substrate 110 may have a double-layer structure or a multilayer structure having three or more layers. Of course, the substrate 110 is not limited to such structures.

A second electrode 128 may be formed over the substrate 110. The second electrode 128 will contact a second semiconductor layer 124, which is included in the light emitting structure 120.

In the case, the second electrode 128 electrically connected to the second semiconductor layer 124, and formed through the first semiconductor layer 122 and the active layer 126.

A first recess (not shown) having a first width d1 may be formed at the light emitting structure 120. An insulating layer 140 may be disposed in the first recess, or interposed among the first electrode 127, the second electrode 128, the first semiconductor layer 122 and second semiconductor layer 124.

In this case, the insulating layer 140 is disposed on the second electrode 128, to prevent the second electrode 128 from contacting constituent elements of the light emitting structure 120, namely, a first semiconductor layer 122 and an active layer 126.

The insulating layer 140, which is disposed in the first recess, may define a second recess (not shown) having a second width d2 narrower than the first width d1.

The second electrode 128 is disposed in the second recess while contacting a portion of the second semiconductor layer 124.

In this case, the first and second recess may include at least one of a groove. The insulating layer 140 may be made of a material such as SiO₂ or Si₃N₄.

A first electrode 127 may be disposed on the insulating layer 140, to be electrically connected to the first semiconductor layer 122.

That is, the first electrode 127 may be insulated from the second electrode 128 by the insulating layer 140. The first electrode 127 is exposed, at one surface thereof, to an outside of the light emitting structure 120, to be electrically connected to an electrode pad 150. Of course, the first electrode 127 is not limited to the above-described structure.

The first electrode 127 may include a reflection film 127a and a light transmitting electrode 127b. The reflection film 127a and light transmitting electrode 127b may be formed through simultaneous curing thereof, so that excellent bonding force may be obtained.

Referring to FIG. 1, it can be seen that the reflection film 127a and light transmitting electrode 127b have the same width and the same length. However, the reflection film 127a and light transmitting electrode 127b may be different in terms of at least one of width and length. Of course, the reflection film 127a and light transmitting electrode 127b are not limited to the above-described conditions.

The light emitting structure 120 may be disposed on at least one of the first and second electrodes 127 and 128. As described above, the light emitting structure 120 may include the first semiconductor layer 122, active layer 126 and second semiconductor layer 124. The following description will be given in conjunction with the case in which the active layer 126 is interposed between the first and second semiconductor layers 122 and 124.

The first semiconductor layer 122 may inject holes into the active layer 126. The first semiconductor layer 122 may be implemented by a p-type semiconductor layer. The p-type semiconductor layer may be made of, for example, a semiconductor material having a formula of InₓAl_{y}Ga_{1-x-y}N (0≦x≦1, 0≦y≦1, and 0≦x+y≦1), for example, GaN, AlN, AlGaN, InGaN, InN, InAlGaN, or AlInN.

The p-type semiconductor layer may be doped with a p-type dopant such as Mg, Zn, Ca, Sr, Ba or the like.

The active layer 126 may be disposed over the first semiconductor layer 122. The active layer 126 is a region where electrons and holes are recombined. In accordance with recombination of electrons and holes, the active layer 126 transits to a lower energy level, so that it may generate light having a wavelength corresponding to the energy level.

The active layer 126 may be made of, for example, a semiconductor material having a formula of InₓAl_{y}Ga_{1-x-y}N (0≦x≦1, 0≦y≦1, and 0≦x+y≦1). The active layer 126 may have a single quantum well structure or a multi-quantum well (MQW) structure. Alternatively, the active layer 126 may include a quantum wire structure or a quantum dot structure.

The second semiconductor layer 124 may be implemented by an n-type semiconductor layer. The n-type semiconductor layer may be made of one of GaN-based compound semiconductor materials such as GaN, AlGaN, and InGaN, and may be doped with an n-type dopant.

The second semiconductor layer 124 may supply electrons to the active layer 126. The second semiconductor layer 124 may be formed of a first-conductivity-type semiconductor layer alone, or may further include an undoped semiconductor layer disposed beneath the first-conductivity-type semiconductor layer. Of course, the second semiconductor layer 124 is not limited to such structures.

The first-conductivity type semiconductor layer may be, for example, an n-type semiconductor layer. In this case, the n-type semiconductor layer may be made of a semiconductor material having a formula of InₓAl_{y}Ga_{1-x-y}N (0≦x≦1, 0≦y≦1, and 0≦x+y≦1), for example, GaN, AlN, AlGaN, InGaN, InN, InAlGaN, or AlInN. The n-type semiconductor layer may be doped with an n-type dopant such as Si, Ge, or Sn

The undoped semiconductor layer is formed to achieve an enhancement in the crystallinity of the first-conductivity-type semiconductor layer. The undoped semiconductor layer is identical to the first-conductivity-type semiconductor layer, except that it has considerably low electrical conductivity, as compared to the first-conductivity-type semiconductor layer, because there is no n-type dopant injected into the undoped semiconductor layer.

The second semiconductor layer 124 may be formed by supplying silane (SiH₄) gas containing a first dopant such as NH₃, TMGa, or Si. The second semiconductor layer 124 may have a multilayer structure. The second semiconductor layer 124 may further include a clad layer.

The first semiconductor layer 122, active layer 126, and second semiconductor layer 124 may be formed using a metal organic chemical vapor deposition (MOCVD) method, a chemical vapor deposition (CVD) method, a plasma-enhanced chemical vapor deposition (PECVD) method, a molecular beam epitaxy (MBE) method, a hydride vapor phase epitaxy (HVPE) method, or the like. Of course, the formation method is not limited to the above-described methods.

The concentrations of the dopants in the first and second semiconductor layers 122 and 124 may be uniform or non-uniform. That is, various multilayer semiconductor layer structures may be provided, although the present disclosure is not limited thereto.

Contrary to the above-described embodiment, the first semiconductor layer 122 may be implemented by an n-type semiconductor layer, and the second semiconductor layer 124 may be implemented by a p-type semiconductor layer. That is, the formation positions of the first and second semiconductor layers 122 and 124 with respect to the active layer 126 may be reversed. However, the following description will be given in conjunction with the case in which the first semiconductor layer 122 is implemented using a p-type semiconductor layer, and is disposed near the substrate 110.

An concavo-convex pattern 129 may be formed at a portion or an entire portion of the semiconductor layer 124, although the present disclosure is not limited thereto.

The conversion layer 130 may be disposed over the second semiconductor layer 124 of the light emitting structure 120. The conversion layer 130 may diffuse first light (not shown) emitted from the active layer 126, and may convert the first light into second light (not shown) having a different wavelength than the first light.

That is, the conversion layer 130 includes a first layer 132 for diffusing the first light, and a second layer 134 for absorbing the first light, and converting the absorbed first light into the second light, which has a different wavelength than the first light.

At least one of the first and second layers 132 and 134 may have a multilayer structure, although the present disclosure is not limited thereto.

Although not shown in FIGS. 1 and 2, a passivation layer (not shown) may be disposed on side surfaces of the electrode pad 150 and light emitting structure 120, in order to prevent a short circuit from occurring between the electrode pad 150 and the light emitting structure 120. Of course, the present disclosure is not limited to the above-described structure.

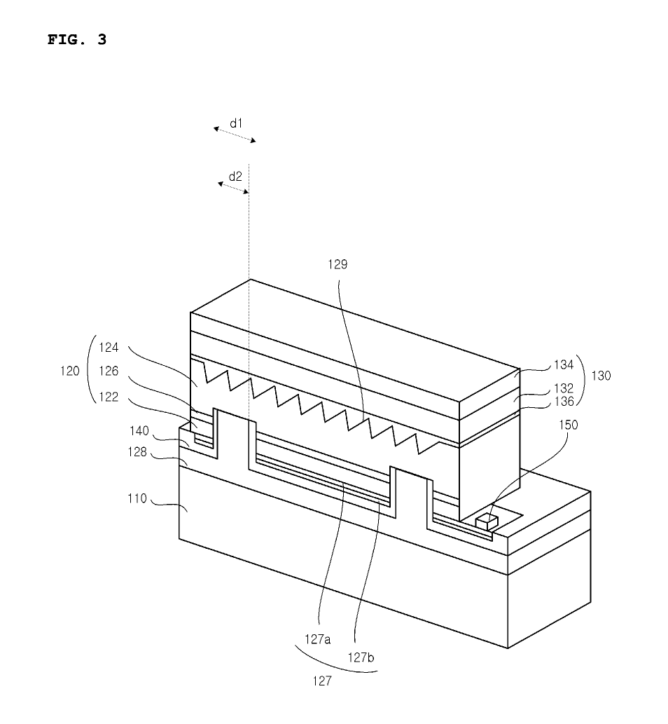

FIG. 3 is a cross-sectional perspective view of the light emitting device in accordance with another embodiment.

The configuration of FIG. 3, which is similar to the configuration of FIGS. 1 and 2, will be described in brief or will not be described.

With reference to FIG. 3 a light emitting device 100 as embodied and broadly described herein may include a conversion layer 130 including a first layer 132, a second layer 134, and a third layer 136.

Since the first and second layers 132 and 134 are identical to those of FIG. 2, no description thereof will be given.

The third layer 136 is interposed between the first layer 132 and the second semiconductor layer 124. The third layer 136 may be made of a transparent material having bondability to bond the first layer 132 and second semiconductor layer 124.

The third layer 136 may have a lower refractive index than the second semiconductor layer 124. For example, when the second semiconductor layer 124 is doped with Si, it may have a lower refractive index than Si, which exhibits an index of reflection ranging from 1.44 to 1.56.

The third layer 136 may include a polymer material mixed with methyl iso-butylketone (MTB) and may have an refractive index ranging from 0.5 to 1.3. The third layer 136 may also have voids. The voids may have an refractive index corresponding to 1. The refractive index of the third layer 136 may be reduced by increasing the content of the voids in the third layer 136.

The third layer 136 may be made of a material exhibiting a lower refractive index than the second semiconductor layer 124 in order to prevent back scattering of at least one of the first light and second light incident from at least one of the first and second layers 132 and 134, and the active layer 126.

That is, as the third layer 136 has a lower refractive index than the second semiconductor layer 124, at least one of the first light and the second light may be incident toward a side surface of the second semiconductor layer 124 without being incident from the first and second layers 132 and 134 in a rearward direction, that is, toward the active layer 126.

The third layer 136 also functions as a bonding layer between the first layer 132 and the second semiconductor layer 124, to increase a bonding force (coupling force) between the first layer 132 and the second semiconductor layer 124.

Thus, the third layer 136 may prevent the second semiconductor layer 124 from being degraded by heat generated from a phosphor (not shown) contained in the second layer 134.

In the illustrated embodiment, the third layer 136 is illustrated as being arranged over the entire upper surface of the second semiconductor layer 124. However, the first layer 132 may be disposed at a peripheral region (not shown) of the second semiconductor layer 124 surrounding a central region (not shown) of the second semiconductor layer 124 while being spaced apart from the central region of the second semiconductor layer 124. In this case, the third layer 136 may be disposed only at the central region. Of course, the present disclosure is not limited to the above-described structures.

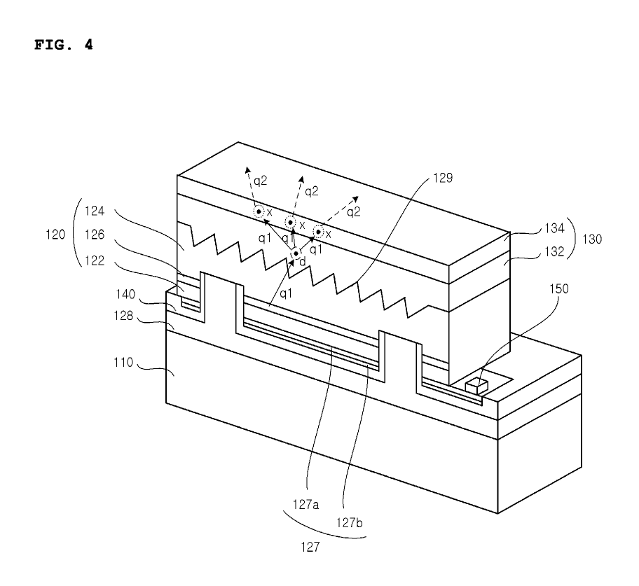

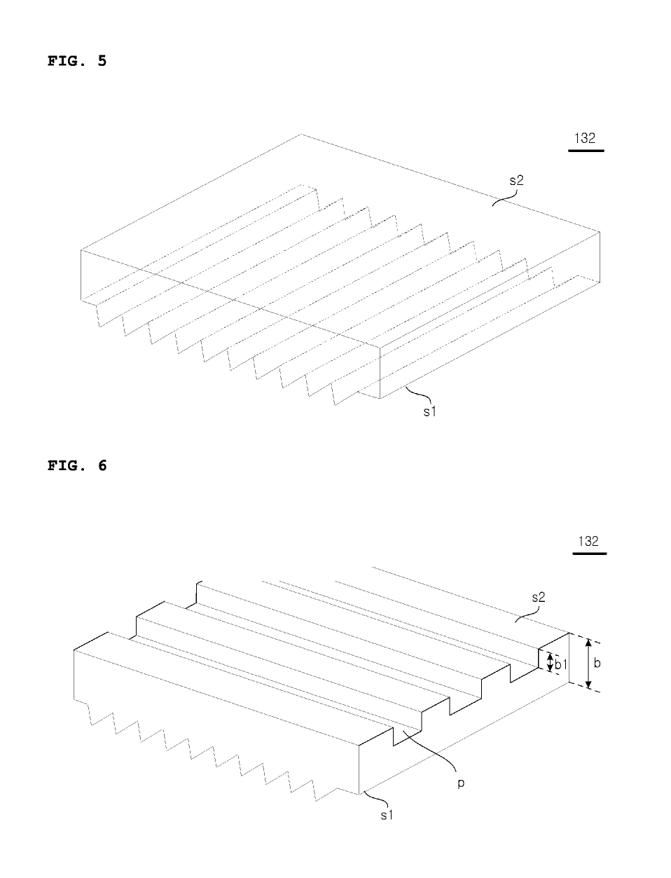

FIG. 4 is a view illustrating operation of the light emitting device, and FIGS. 5 to 9 are perspective views illustrating various arrangements of a first layer as embodied and broadly described herein.

FIGS. 4 to 9 are associated with the structure of the light emitting device shown in FIGS. 1 and 2. However, the light emitting device structure shown in FIG. 3 may perform the same operation as that of FIGS. 1 and 2, although the present disclosure is not limited thereto.

With reference to FIGS. 4 to 9, the light emitting device 100 may include the conversion layer 130, which absorbs first light q1 emitted from the active layer 126, and emits second light q2 having a longer wavelength than the first light q1.

As described above, the conversion layer 130 may include the first layer 132, which diffuses the first light q1, and the second layer 134. The second layer 134 absorbs the first light q1, which is incident from at least one of the first layer 132 and the active layer 126, and converts the first light q1 into the second light q2, which has a different wavelength than the first light q1.

The conversion layer 130 may further include the third layer 136, which is shown in FIG. 3. The third layer 136 may be interposed between the first layer 132 and the second semiconductor layer 124. Of course, the present disclosure is not limited to the above-described structure.

Although each of the first and second layers 132 and 134 has been illustrated and described as a single-layer structure, it may have a multilayer structure. Of course, the present disclosure is not limited to the above-described structures.

The first layer 132 may diffuse the first light q1 emitted from the active layer 126. The first layer 132 is made of a material having a light transmittance of 0 to 80%. For example, the first layer 132 may be made of at least one of polyimide and a dielectric. The first layer 132 may contain at least one of a light diffusion agent d and a light dispersion agent (not shown), although the present disclosure is not limited thereto.

Although the first layer 132 has been described as including at least one of polyimide and a dielectric, and a light diffusion agent d in the illustrated embodiment, it may include only one of the above materials. Of course, the present disclosure is not limited to the above-described conditions.

The light diffusion agent d may vary the emission direction of the first light q1, and may disperse the first light q1 in various directions.

The second layer 134 may contain at least one kind of phosphor x absorbing the first light q1 and converting the first light q1 into the second light q2, which has a different wavelength than the first light q1.

Although the second layer 134 has been described as including a certain kind of florescent substance x to wavelength-convert the first light q1 into the second light q2 in the illustrated embodiment, the present disclosure is not limited thereto.

With Reference to FIGS. 5 to 9, the first layer 132 may include a first surface s1 disposed adjacent to the second semiconductor layer 124, and a second surface s2 disposed adjacent to the second layer 134.

An concavo-convex pattern (not shown) may be formed at the first surface s1 to correspond to the concavo-convex pattern 129 of the second semiconductor layer 124.

That is, the first surface s1 may be formed with the concavo-convex pattern corresponding to the concavo-convex pattern 129 in a region where the first surface s1 contacts the second semiconductor layer 124. When the third layer 136 is arranged as shown in FIG. 4, the concavo-convex pattern may not be formed at the first surface s1 of the first layer 132. Of course, the present disclosure is not limited to the above-described structures.

Although the first layer 132 has been described as having the concavo-convex pattern at the first surface s1 while being flat at the second surface s2, in the embodiment of FIG. 5, an concavo-convex pattern corresponding to the above-described concavo-convex pattern may be formed at the second surface s2. Of course, the present disclosure is not limited to the above-described structures.

With Reference to FIG. 6, 7 or 8, the first layer 132 may be formed with the concavo-convex pattern at the first surface s1 while being formed with one of first to third diffusion patterns p, p1, and p2 at the second surface s2.

The first diffusion pattern p, which is shown in FIG. 6, has a stripe structure. The first diffusion pattern p may have a depth b1 smaller than a thickness b of the first layer 132.

The depth b1 of the first layer 132 may be 10 to 1,000 μm. When the depth b1 is less than 10 μm, it may not be easy to achieve formation of the first diffusion pattern p and easy diffusion of the first light q1. On the other hand, when the depth b1 exceeds 1,000 μm, a reduction in light amount may occur due to diffusion of the first light q1.

The first diffusion pattern p may have a semicircular or polygonal cross-section. The first diffusion pattern p may have an irregular or regular stripe structure.

The second diffusion pattern p1, which is shown in FIG. 7, has a lattice structure. The third diffusion pattern p2, which is shown in FIG. 8, has a square dot structure.

Alternatively, the third diffusion pattern p2 may have a semicircular dot structure. Of course, the present disclosure is not limited to the above-described structures.

The second diffusion pattern p1 may have a depth (not shown) equal to the depth b1 of the first diffusion pattern p1, and the third diffusion pattern p2 may have a height (not shown) equal to the depth b1, although the present disclosure is not limited thereto.

That is, the first to third diffusion patterns p, p1, and p2 may have a structure capable of achieving easy diffusion of the first light q1, although the present disclosure is not limited thereto.

Although not illustrated in this embodiment, the second diffusion pattern p1 may consist of openings formed at the second face s2 of the first layer 132. The second layer 134 may be disposed in the openings. The second layer 134 may be disposed only within the first layer 132, although the present disclosure is not limited thereto.

As shown in FIG. 9, the first layer 132 may be formed with the concavo-convex pattern at the first surface s1 while being formed, at the second surface s2, with a hole pattern h disposed to correspond to the concavo-convex pattern 129 of the second semiconductor layer 124.

The hole pattern shown in FIG. 9 may have at least one of a circular shape and a polygonal shape. At the second layer 134 disposed over the first layer 132, a protrusions pattern (not shown) may be formed to correspond to the hole pattern. Of course, the present disclosure is not limited to the above described structure.

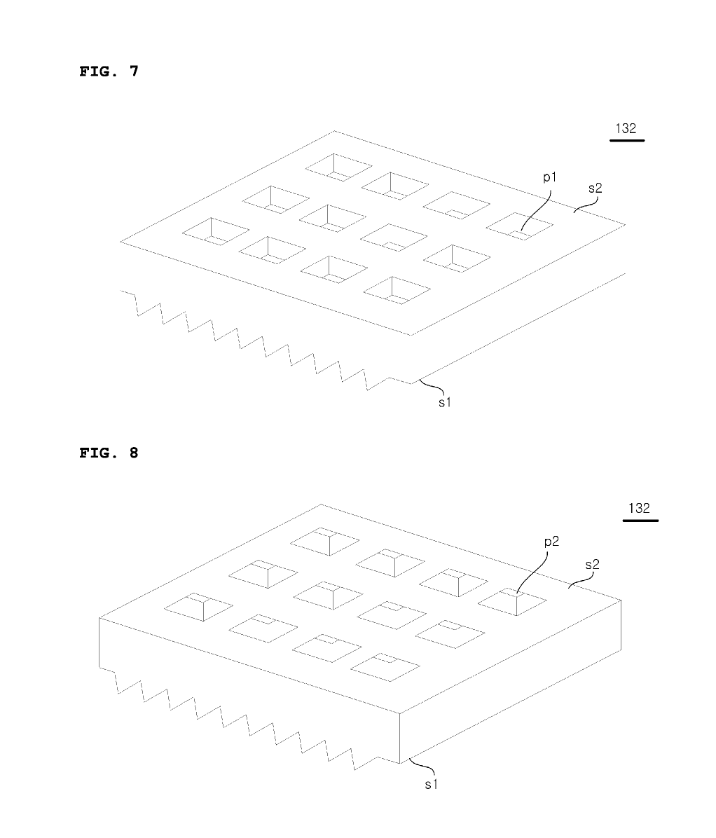

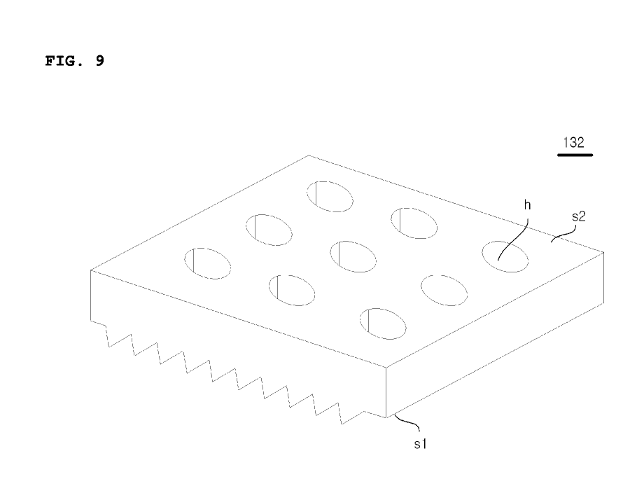

FIG. 10 is a perspective view illustrating a light emitting device in accordance with another embodiment as broadly described herein, FIG. 11 is a cross-sectional perspective view of the light emitting device in accordance with another embodiment.

The constituent elements of the light emitting device of FIGS. 10 and 11, which are identical to those of FIGS. 1 to 9, will be described in brief or will not be described. Also, these constituent elements may be designated by reference numerals different from those of FIGS. 1 to 9, respectively.

With reference to FIGS. 10 and 11, the light emitting device 180 may include a substrate 181 including first and second substrate portions 181a and 181b spaced apart from each other, a light emitting structure 184 formed on the substrate 181, and a conversion layer 185 formed over the light emitting structure 184. The light emitting structure 184 may include a first semiconductor layer 184a, a second semiconductor layer 184b, and an active layer 184c interposed between the first and second semiconductor layers 184a and 184b.

The conversion layer 185 has the same configuration as the conversion layer 130 described with reference to FIGS. 1 to 9 and, as such, no description thereof will be given.

A first recess (not shown) may be formed at a portion of the light emitting structure 184 disposed on the second substrate portion 181b. The first recess may extend from the first semiconductor layer 184a to a portion of the second semiconductor layer 184b.

Second electrodes 182 may be disposed on the first and second substrate portions 181a and 181b, respectively. A first electrode 187 may be interposed between the second electrode 182 disposed on the first substrate portion 181 and the first semiconductor layer 184a while contacting the first semiconductor layer 184a. The first electrode 187 may include a reflection film 187a and a light transmitting electrode 187b.

The second electrode 182 disposed on the second substrate portion 182 may extend through the first recess, to contact the second semiconductor layer 184b. Another first electrode 187 may be interposed between the second electrode 182 disposed on the second substrate portion 181b and the first semiconductor layer 184a. The light emitting device 180 may further include an insulating layer 183 interposed between the second electrode 182 and the first electrode 187, which are disposed on the second substrate portion 181b, while being disposed on peripheral portions of the second electrode 182 and the first electrode 187, which are disposed on the first substrate portion 181a.

The insulating layer 183 may also be disposed in the first recess while defining a second recess (not shown) having a narrower width than the first recess. The second electrode 187 on the second substrate portion 181b may be disposed in the second recess while contacting the second semiconductor layer 184b.

In the light emitting device 180 shown in FIGS. 10 and 11, it may not be disposed electrode pad, different than the light emitting device 100 shown in FIGS. 1 to 9.

That is, the light emitting device 180 has an advantage in that it may be possible to eliminate the process for arranging an electrode pad because the substrate 181 is divided into the first and second substrate portions 181a and 181b spaced apart from each other.

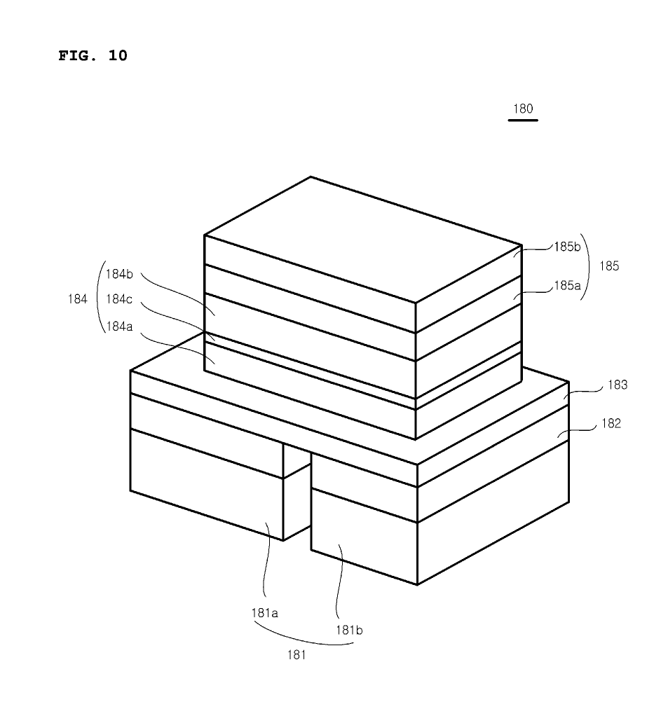

FIG. 12 is a cross-sectional view of a light emitting device package including a light emitting device as embodied and broadly described herein.

With reference to FIG. 12, the light emitting device package 200 may include a body 210 formed with a cavity, a light emitting device 220 mounted on a bottom of the body 210, and a resin material 230 filling the cavity. The resin material 230 may contain a phosphor 240.

The body 210 may be made of at least one of a resin material such as polyphthalamide (PPA), silicon (Si), aluminum (Al), aluminum nitride (AlN), liquid crystal polymer such as photo sensitive glass (PSG), polyamide 9T (PA9T), sindiotactic polystyrene (SPS), a metal, sapphire (Al2O3), beryllium oxide (BeO), and ceramic, or may be a printed circuit board (PCB). The body 210 may be formed by an injection molding process, an etching process or the like, although the present disclosure is not limited thereto.

The body 210 may have an inclined surface at an inner surface thereof. In accordance with the inclination of the inclined surface, the reflection angle of light emitted from the light emitting device 220 may be varied. Thus, the orientation angle of outwardly emitted light may be adjusted.

When viewed from the top side, the cavity, which is formed at the body 210, may have a circular, rectangular, polygonal or elliptical shape. In particular, the cavity may have curved corners. Of course, the cavity is not limited to the above-described shapes.

The light emitting device 220 is mounted on the bottom of the body 210. For example, the light emitting device 220 may be the light emitting device illustrated in FIG. 1 and described with reference to FIG. 1. The light emitting device 220 may be, for example, a colored light emitting device to emit red, green, blue and white light, or an ultraviolet (UV) light emitting device to emit ultraviolet light, although it is not limited thereto. One or more light emitting devices may be mounted.

Meanwhile, the body 210 may include a first electrode 252 and a second electrode 254. The first and second electrodes 252 and 254 may be electrically connected to the light emitting device 220, to supply electric power to the light emitting device 220.

The first and second electrodes 252 and 254 are electrically isolated from each other. The first and second electrodes 252 and 254 may function to reflect light generated from the light emitting device 220, thereby enhancing light efficiency. The first and second electrodes 252 and 254 may also outwardly dissipate heat generated from the light emitting device 220.

The first and second electrodes 252 and 254 may be made of at least one of titanium (Ti), copper (Cu), nickel (Ni), gold (Au), chromium (Cr), tantalum (Ta), platinum (Pt), tin (Sn), silver (Ag), phosphor (P), aluminum (Al), indium (In), palladium (Pd), cobalt (Co), silicon (Si), germanium (Ge), hafnium (Hf), ruthenium (Ru), and iron (Fe), or an alloy thereof. The first and second electrodes 252 and 254 may have a single-layer structure or a multilayer structure, although the present disclosure is not limited thereto.

The resin material 230 may fill the cavity, and may include a phosphor 240. The resin material 230 may be made of transparent silicon, epoxy resin, or other resin materials. The resin material 230 may be formed by filling the cavity with an encapsulating material, and curing the filled material using ultraviolet light or heat.

The kind of the phosphor 240 may be selected in accordance with the wavelength of light emitted from the light emitting device 220 in order to realize emission of white light.

The phosphor 240 contained in the resin material 230 may be a blue, bluish green, green, yellowish green, yellow, yellowish red, orange, or red light-emitting phosphor in accordance with the wavelength of light emitted from the light emitting device 220.

That is, the phosphor 240 may be excited by light emitted from the light emitting device 220 at a first wavelength, to generate light of a second wavelength. For example, when the light emitting device 220 is a blue light emitting diode, and the phosphor 240 is a yellow phosphor, the yellow phosphor is excited by blue light, thereby emitting yellow light. In this case, the light emitting device package 220 may provide white light as the blue light generated from the blue light emitting diode and the yellow light generated in accordance with the excitation by the blue light are mixed.

Similarly, when the light emitting device 220 is a green light emitting diode, a magenta phosphor or a mixture of blue and red phosphors may be used as the phosphor 240. Also, when the light emitting device 220 is a red light emitting diode, a cyan phosphor or a mixture of blue and green phosphors may be used as the phosphor 240.

The phosphor 240 may be a known phosphor such as a YAG-based, TAG-based, sulfide-based, silicate-based, aluminate-based, nitride-based, carbide-based, nitridosilicate-based, borate-based, fluoride-based, or phosphate-based phosphor.

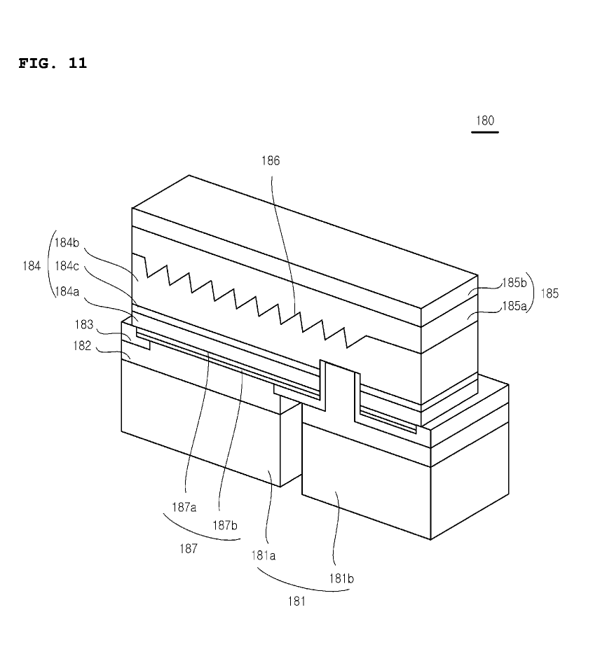

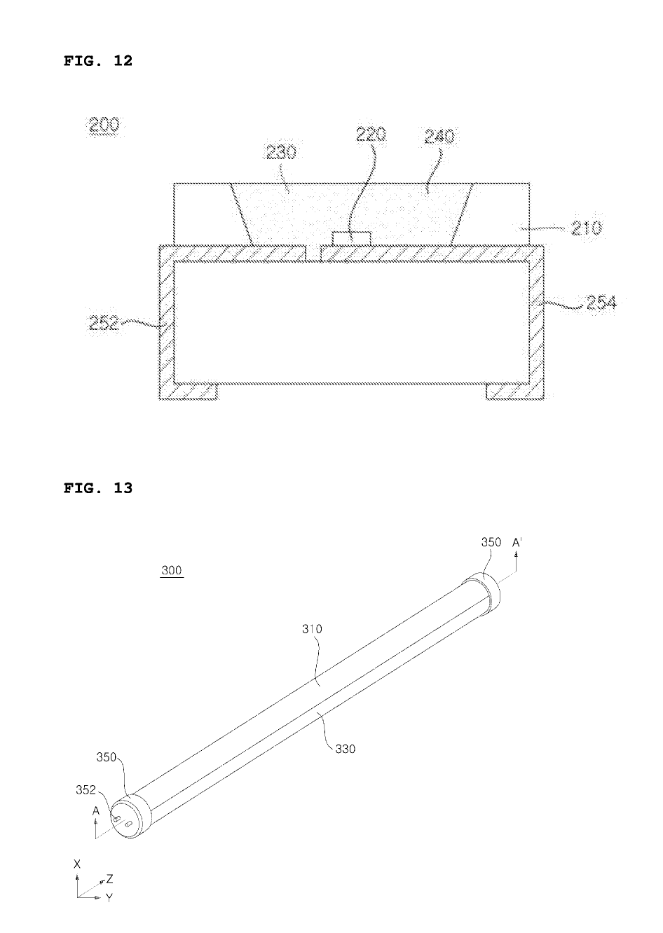

FIG. 13 is a perspective view of a lighting apparatus including a light emitting device in accordance embodiments as broadly described herein, FIG. 14 is a sectional view of the lighting apparatus taken along the line A-A of the lighting apparatus shown in FIG. 13.

In the following description, to explain the shape of the lighting apparatus 300 according to the illustrated embodiment in more detail, the longitudinal direction of the lighting apparatus 300 is referred to as a “longitudinal direction Z”, a horizontal direction perpendicular to the longitudinal direction Z is referred to as a “horizontal direction Y”, and a height direction perpendicular to both the longitudinal direction Z and the horizontal direction Y is referred to as a “height direction X”.

That is, FIG. 14 is a cross-sectional view taken along a Z-X plane of the lighting apparatus 300 shown in FIG. 13, and viewed in the horizontal direction Y.

With reference to FIGS. 13 and 14, the lighting apparatus 300 may include a body 310, a cover 330 coupled to the body 310, and end caps 350 located at both ends of the body 310.

A light emitting device module 340 is coupled to a lower surface of the body 310. The body 310 may be made of a metal material exhibiting excellent conductivity and excellent heat radiation effects to outwardly dissipate heat generated from the light emitting device module 340 through an upper surface of the body 310.

The light emitting device module 340 includes a PCB 342, and light emitting device packages 344 each including a light emitting device (not shown). The light emitting device packages 344 may be mounted on the PCB 342 in multiple rows while having various colors, to form a multi-color array. The light emitting device packages 344 may be mounted at the same distance, or may be mounted at different distances to enable brightness adjustment, if necessary. The PCB 342 may be a metal core PCB (MCPCB) or a flame retardant-4 (FR4) PCB.

The cover 330 may have a circular shape to surround the lower surface of the body 310, although the present disclosure is not limited thereto.

The cover 330 protects the light emitting device module 340 from external foreign matter, etc. The cover 330 may contain light diffusion particles to achieve anti-glare effects and uniform emission of light generated from the light emitting device packages 344. At least one of the inner and outer surfaces of the cover 330 may be provided with a prism pattern. Also, a phosphor layer may be coated over at least one of the inner and outer surfaces of the cover 330.

Since the light generated from the light emitting device packages 344 is outwardly emitted through the cover 330, the cover 330 should have high light transmittance and heat resistance sufficient to endure heat generated from the light emitting device packages 344. To this end, the cover 330 may be formed of polyethylene terephthalate (PET), polycarbonate (PC) or polymethylmethacrylate (PMMA).

The end caps 350 may be disposed at both ends of the body 310 and function to seal a power supply device (not shown). Each end cap 350 is provided with power pins 352, so that the lighting apparatus 300 in accordance with the illustrated embodiment may be directly connected to a terminal without an additional connector.

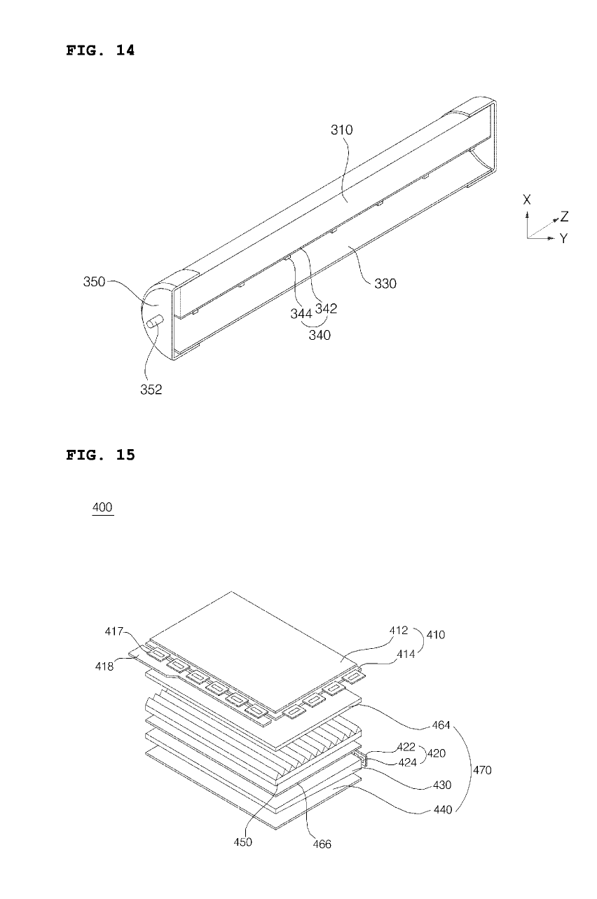

FIG. 15 is a perspective view of a liquid crystal display apparatus including a light emitting device in accordance with an embodiment as broadly described herein.

FIG. 15 illustrates an edge-light type liquid crystal display apparatus 400. The liquid crystal display apparatus 400 may include a liquid crystal display panel 410 and a backlight unit 470 to supply light to the liquid crystal display panel 410.

The liquid crystal display panel 410 may display an image using the light supplied from the backlight unit 470. The liquid crystal display panel 410 may include a color filter substrate 412 and a thin film transistor substrate 414, which are opposite each other with liquid crystals interposed therebetween.

The color filter substrate 412 may realize the color of an image displayed on the liquid crystal display panel 410.

The thin film transistor substrate 414 is electrically connected to a PCB 418, on which a plurality of circuit elements is mounted, by means of a drive film 417. The thin film transistor substrate 414 may apply drive voltage provided by the PCB 418 to liquid crystals in response to a drive signal transmitted from the PCB 418.

The thin film transistor substrate 414 may include pixel electrodes and thin film transistors in the form of thin films formed on another substrate made of a transparent material such as glass or plastic.

The backlight unit 470 includes a light emitting device module 420 to emit light, a light guide plate 430 to change light emitted from the light emitting device module 420 into planar light and to transmit the planar light to the liquid crystal display panel 410, a plurality of films 450, 466 and 464 to achieve uniformity in brightness distribution and improved vertical incidence of light emerging from the light guide plate 430, and a reflection sheet 440 to reflect light emitted rearwards from the light guide plate 430 toward the light guide plate 430.

The light emitting device module 420 may include a plurality of light emitting device packages 424 and a PCB 422 on which the plurality of light emitting device packages 424 is mounted to form an array.

Meanwhile, each light emitting device package 424 includes a light emitting device, which may be identical to that of FIG. 1 and, as such, no description thereof will be given.

The backlight unit 470 may include a diffusion film 466 to diffuse light incident thereupon from the light guide plate 430 toward the liquid crystal display panel 410, and a prism film 450 to condense the diffused light so as to enhance vertical light incidence. The backlight unit 470 may further include a protection film 464 to protect the prism film 450.

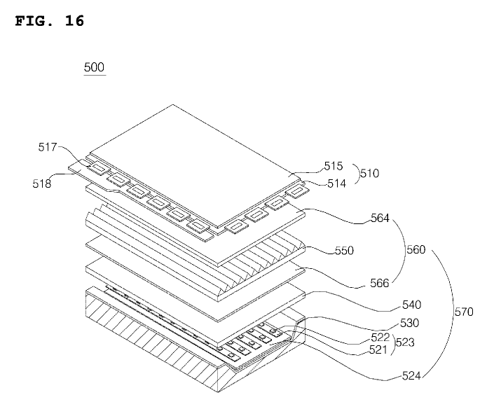

FIG. 16 is a perspective view of a liquid crystal display apparatus including a light emitting device in accordance with another embodiment as broadly described herein.

The same configuration as that illustrated in FIG.

15 and described with reference to FIG. 15 will not be repeatedly described in detail.

FIG. 16 illustrates a direct type liquid crystal display apparatus 500 including a liquid crystal display panel 510 and a backlight unit 570 to supply light to the liquid crystal display panel 510.

The liquid crystal display panel 510 is identical to that of FIG. 15 and, as such, no detailed description thereof will be given.

The backlight unit 570 may include a plurality of light emitting device modules 523, a reflection sheet 524, a lower chassis 530 in which the light emitting device modules 523 and reflection sheet 524 are accommodated, and a diffusion sheet 540 and a plurality of optical films 560, which are disposed over the light emitting device modules 523.

Each light emitting device module 523 may include a plurality of light emitting device packages 522, and a PCB 521 on which the plurality of light emitting device packages 522 is mounted to form an array.

The reflection sheet 524 reflects light generated by the light emitting device packages 522 toward the liquid crystal display panel 510, to achieve an enhancement in light utilization efficiency.

Meanwhile, the light generated from the light emitting device modules 523 is incident upon the diffusion sheet 540. The optical films 560 are disposed over the diffusion sheet 540. The optical films 560 may include a diffusion film 566, a prism film 550 and a protection film 564.

In the embodiments, the lighting apparatus 400 and liquid crystal display apparatus 500 and 600 may be included in the lighting system and a lighting device including a light emitting device package may be included in the lighting system.

In the light emitting device according to one of the embodiments, it may be possible to diffuse first light emitted from the light emitting structure and to wavelength-convert the first light into second light because the conversion layer including the first and second layers is disposed on the light emitting structure. Also, it may be possible to prevent the light emitting structure from being degraded due to the phosphor contained the second layer by the first layer.

In addition, in the light emitting device according to one of the embodiments, the third layer, which has a low refractive index, is interposed between the light emitting structure and the first layer. In this case, it may be possible to prevent back scattering of the first light and second light from the first and third layer toward the light emitting structure, and thus to achieve an enhancement in light emission efficiency.

A light emitting device as embodied and broadly described herein may allow which exhibits improved luminous efficacy, reduces drive voltage, and improves safety and reliability.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. 1. A light emitting device, comprising:
a light emitting structure comprising a first semiconductor layer, a second semiconductor layer, an active layer interposed between the first and second semiconductor layers;
a first electrode electrically connected to the first semiconductor layer;
a second electrode electrically connected to the second semiconductor layer, and formed through the first semiconductor layer and the active layer;
an insulating layer disposed between the second electrode and the first electrode, between the second electrode and the first semiconductor layer; and,
a conversion layer disposed on the second semiconductor layer, the conversion layer comprising a first layer to diffuse first light emitted from the active layer, and a second layer to absorb the first light diffused by the first layer and to convert the first light into second light having a different wavelength than the first light.

2. The light emitting device of claim 1, wherein the first layer comprises a first surface disposed adjacent to the second semiconductor layer, and a second surface disposed opposite the first surface while being adjacent to the second layer, and
wherein at least one of the first and second surfaces is formed with a diffusion pattern.

3. The light emitting device of claim 2, wherein the diffusion pattern has at least one of a lattice structure, a stripe structure, and a dot structure.

4. The light emitting device of claim 1, wherein the second semiconductor layer is formed with a first concavo-convex pattern, and
wherein at least a portion of the first layer is formed with a second concavo-convex pattern corresponding to the first irregularity pattern.

5. The light emitting device of claim 1, wherein the second semiconductor layer is formed with a first concavo-convex pattern, and
wherein at least a portion of the first layer is formed with a hole pattern at a position corresponding to the first concavo-convex pattern.

6. The light emitting device of claim 5, wherein the hole pattern has at least one of a circular shape and a polygonal shape.

7. The light emitting device of claim 5, wherein the second layer is formed with a protrusions pattern disposed within of the hole pattern.

8. The light emitting device of claim 1, wherein the first layer comprises at least one of polyimide and dielectric.

9. The light emitting device of claim 1, wherein the first layer comprises at least one of a light diffusion agent and a light dispersion agent.

10. The light emitting device of claim 1, wherein the first layer has a light transmittance of 50 to 80%.

11. The light emitting device of claim 1, wherein the first layer has a thickness of 10 to 1,000 μm.

12. The light emitting device of claim 2, wherein the second layer comprises at least one kind of phosphor.

13. The light emitting device of claim 1, wherein the conversion layer comprises a third layer interposed between the second semiconductor layer and the first layer, the third layer having a lower refractive index than the second semiconductor layer.

14. The light emitting device of claim 13, wherein the third layer prevents back scattering of the first light and the second light, which are emitted from at least one of the first layer, the second layer, and the active layer.

15. The light emitting device of claim 13, wherein the first layer is spaced apart from a central region of the second semiconductor layer while contacting a peripheral region of the second semiconductor layer surrounding the central region, and
wherein the third layer is disposed at the central region.

16. The light emitting device of claim 1, further comprising:
an electrode pad spaced apart from a side surface of the light emitting structure while contacting the first electrode.

17. The light emitting device of claim 16, further comprising:
a passivation layer interposed between the side surface of the light emitting structure and the electrode pad.

18. A light emitting device, comprising:
a substrate comprising first and second substrate portions spaced apart from each other;
a light emitting structure dispose on the substrate, the light emitting structure comprising a first semiconductor layer, a second semiconductor layer, an active layer interposed between the first and second semiconductor layers;
a first electrode interposed between the first substrate and the first semiconductor layer, and electrically connected to the first semiconductor layer;
a second electrode disposed on the second substrate, formed through the first semiconductor layer and the active layer, and electrically connected to the second semiconductor layer;
an insulating layer disposed between the second electrode and the first electrode, between the second electrode and the first semiconductor layer; and,
a conversion layer disposed on the second semiconductor layer, the conversion layer comprising a first layer to diffuse first light emitted from the active layer, and a second layer to absorb the first light diffused by the first layer and to convert the first light into second light having a different wavelength than the first light.

19. The light emitting device of claim 18, wherein at least one of the first to third layers has a different refractive index and, includes at least two layers.

20. A light emitting device, comprising:
a substrate;
a light emitting structure dispose on the substrate, the light emitting structure comprising a first semiconductor layer, a second semiconductor layer, an active layer interposed between the first and second semiconductor layers;
a first electrode electrically connected to the first semiconductor layer;
a second electrode electrically connected to the second semiconductor layer, and formed through the first semiconductor layer and the active layer;
an insulating layer disposed between the second electrode and the first electrode, between the second electrode and the first semiconductor layer; and,
a conversion layer disposed on the second semiconductor layer, to perform diffusion and wavelength conversion for first light emitted from the active layer,
wherein the conversion layer comprises:
a first layer to diffuse the first light, the first layer being formed with at least one opening at one or more surfaces of the first layer; and
a second layer disposed in the at least one opening, to absorb the first light and to convert the absorbed first light into second light having a different wavelength than the first light.
